(19) United States
(12) Patent Application Publication
(10) Pub. No.: US 2010/0143608 A1
(43) Pub. Date: Jun. 10, 2010

(54) METHOD AND DEVICE FOR PREPARING A MULTILAYER COATING ON A SUBSTRATE

(75) Inventors: Jean-Christophe Ruiz, Laudun l'Ardoise (FR); Bruno Fournel, Venejan (FR); Stephanie Thollon, Salles (FR); Sebastien Donet, Meaudre (FR)

Correspondence Address: OBLON, SPIVAK, MCCLELLAND MAIER & NEUSTADT, L.L.P., 1940 DUKE STREET, ALEXANDRIA, VA, 22314, US

(73) Assignee: COMMISSARIAT A L'ENERGIE ATOMIQUE, PARIS (FR)

(21) Appl. No.: 12/598,530

(22) PCT Filed: Apr. 29, 2008
(86) PCT No.: PCT/EP08/55208

§ 371 Date: Dec. 16, 2009

(30) Foreign Application Priority Data
May 2, 2007 (FR) 0754815

(51) Int. Cl. C23C 16/06; C23C 16/513

(52) U.S. Cl. 427/576; 427/250; 118/724; 977/773

(57) ABSTRACT

Method for preparing a substrate comprising a solid support and a plurality of layers on the support; at least one layer consisting of a uniform, homogeneous, and continuous film of particles of one or more metal oxide(s), or of uniformly, homogeneously, dispersed particles of one or more metal oxide(s), on the support or on an underlying layer; at least one layer consisting of a continuous or discontinuous film of one or more metal(s) or of one or more metal alloy(s), or of dispersed nanoparticles of one or more metal(s) or of one or more metal alloy(s), on the support or on an underlying layer; the method comprising the following steps: a)—impregnating the heated solid support or an already deposited underlying layer with a solution of precursors of the metal oxide or oxides in a supercritical fluid, and depositing a uniform, homogeneous, and continuous film of particles of one or more metal oxide(s), or of uniformly, homogeneously, dispersed particles of one or more metal oxide(s), on the support or on the underlying layer; b)—depositing a continuous or discontinuous film of one or more metal(s) or of one or more metal alloy(s), or dispersed nanoparticles of one or more metal(s) or of one or more metal alloy(s), on the support or on an underlying layer, by chemical vapour deposition CVD, from one or more precursors; the steps a) and b) being carried out in the same chamber, same reactor.

### TECHNICAL FIELD

The invention relates to a method for preparing a multilayer coating, having a plurality of layers on a substrate, where these layers or films may be layers, films, continuous or discontinuous. It relates in particular to thin layers.

The invention also relates to a device for implementing the method.

This method and this device serve in particular to prepare multilayer coatings or heterostructures for catalytic systems.

A first technique for depositing continuous or discontinuous thin layers makes use of supercritical fluids and the chemical vapour deposition process (CVD).

It is in fact known that, on the one hand, the use of supercritical fluids has been developed in connection with the preparation of materials, in particular for the synthesis of thin layers and nanoparticles of metal oxides. The preparation of materials in supercritical medium appears to be an alternative to several conventional methods such as powder grinding, atomisation, sol-gel processes, etc. The use of these fluids serves to control the morphology of the powders and to lower the synthesis temperature. Better catalyst performance has been obtained with the materials prepared by a method employing a supercritical fluid and this is attributed to the decrease in particle size compared to that obtained by conventional methods of the solid-solid type.

The particles in powder form are generally treated, for example sintered, to prepare a material having a dimensional continuity. The supercritical fluids used as a reaction media serve to obtain powders having small dimensions which usually occur in the form of spherical submicron sized aggregates, generally from 100 to 600 nm in size, comprising a substructure consisting of nanometre sized crystallites smaller than 30 nm which, after sintering, have good properties of use [1].

The impregnation in supercritical medium carried out with organometallic precursors is a method for preparing thin layers. The precursors are dissolved in a supercritical fluid and the mixture is then contacted with the substrate. The expansion of the mixture causes the precipitation of the compound on the substrate. Films of silica or mixed oxides of yttrium, barium and copper [2] have thus been prepared. This technology, thanks to the transport properties of the supercritical fluid, serves to cover macroporous parts having very complex geometries such as ceramic foams, honeycomb type monoliths, etc. The deposition on the surface and inside the macroporous structure is very uniform not only from the standpoint of structure and distribution, but also of thickness. It is a wash-coat in the form of a continuous film which may be composed of single or mixed oxides such as TiO₂, ZrO₂, CeO₂, BaO, Al₂O₃, etc., giving it an acidic or basic character according to the intended catalytic application. The crystallites, generally having a size lower than 30 nm, are synthesised in supercritical “SC” medium and deposited in the form of a continuous uniform film on a macroporous support. These catalyst systems have a high specific surface area and are often efficient.

Document [3] (U.S. Pat. No. 4,916,108) describes a method for preparing supported metal catalysts having higher activity.

This method consists in:
dissolving a salt of a catalytic metal such as nickel, iron, copper, cobalt, and precious metals, in a supercritical fluid at a temperature and pressure above the critical temperature and the critical pressure of the fluid, to form a solution of catalytic metal salt in the supercritical fluid;
contacting, for example by immersion, a porous support having a high specific surface area, in particular of ceramic, such as alumina or zirconia, with the solution of catalyst metal salt in the supercritical fluid;
maintaining the solution of catalyst metal salt in the supercritical fluid at the said critical pressure and temperature during the time required for the solution of catalyst metal in the supercritical fluid substantially to penetrate the entire specific surface of the said support; and
lowering either the temperature or the pressure of the said solution below the critical temperature of the fluid to deposit a film of the catalyst metal salt on the surfaces of the said porous support and to convert the supercritical fluid to a recoverable gas.

The porous support containing a metal salt can be heated in a reducing atmosphere to convert the said film of metal salt to a film of pure metal. It is also possible to calcine the porous support containing the metal salt to convert the metal salt to the metal oxide.

In this method, the porous support having a high specific surface area is prepared for example by a casting process which is now described in detail.

The method described in this document comprises at least two separate and distinct steps for preparing the supported metal catalyst, that is first, a step of preparation of the support which is fabricated for example by casting, then a step of impregnation of the said support carried out in supercritical medium, and then optionally a step of reduction in a reducing atmosphere.

These steps are carried out at different locations, in different units, the step involving a supercritical fluid being carried out in particular in a closed chamber or autoclave, heated under pressure. Many handlings and transfer operations of the support between various units, apparatus, operating under fundamentally different conditions and principles are therefore required to obtain the final supported catalyst.

It should be noted that in this document, it is the preparation of the supported metal catalyst and not that of the oxide support that involves a supercritical fluid.

Also known as a method for depositing thin metal layers, continuous or discontinuous, or of dispersed nanoparticles, is the chemical vapour deposition process, which has served in particular for the preparation of efficient catalyst nanomaterials, as described for example in document [4] which describes the preparation or rhodium nanoparticles from 1 to 5 nm in size dispersed on a support by CVD in fluidised bed. The support of the nanoparticles is prepared in a separate step, distinct from that of the particle deposition, and in a different apparatus.

It appears from the above that a need exists in particular for a method for preparing a substrate comprising:
a solid support;
a uniform, homogeneous, and continuous film of one or more metal oxides on the said solid support;
and particles of one or more metal(s) or metal alloy(s) forming a continuous or discontinuous film or dispersed on the said uniform, homogeneous, and continuous film of one or more oxides;

which is inter alia simple, reliable, which comprises a limited number of steps and reactants, which uses a limited number of apparatus, which is clean and non-polluting, and which is readily adaptable to supports having complex geometries.

It is the goal of the present invention to provide a method which supplies this need inter alia.

It is a further goal of the present invention to provide such a method which does not have the drawbacks, defects and disadvantages of the methods of the prior art.

This goal and others are achieved according to the invention by a method for preparing a substrate comprising a solid support and a plurality of layers on the said support;
at least one layer consisting of a uniform, homogeneous, and continuous film of particles of one or more metal oxide(s), or uniformly, homogeneously, dispersed particles of one or more metal oxide(s), on the support or on an underlying layer;
at least one layer consisting of a continuous or discontinuous film of one or more metal(s) or of one or more metal alloy(s), or of dispersed nanoparticles of one or more metal(s) or of one or more metal alloy(s), on the support or on an underlying layer;

the said method comprising the following steps:

a)—impregnating the heated solid support or an already deposited underlying layer with a solution of precursors of the metal oxide or oxides in a supercritical fluid, and depositing a uniform, homogeneous, and continuous film of particles of one or more metal oxide(s), or uniformly, homogeneously, dispersed particles of one or more metal oxide(s), on the support or on the underlying layer;

b)—depositing a continuous or discontinuous film of one or more metal(s) or of one or more metal alloy(s), or dispersed nanoparticles of one or more metal(s) or of one or more metal alloy(s), on the support or on an underlying layer, by chemical vapour deposition CVD, from one or more precursors;

the steps a) and b) being carried out in the same chamber, same reactor.

Based on the support, a step a) followed by step b) may be carried out in succession, or based on the support, a step b) followed by step a) may be carried out in succession.

Each of the steps a) or b) or the succession of steps a) and b) or b) and a) may be repeated from 1 to 10 times.

An organic synthesis step may be carried out after a step a) and/or a step b).

In a preferred embodiment of the inventive method, a substrate is prepared comprising:
a solid support,
a uniform, homogeneous, and continuous film of one or more metal(s) oxide(s) on the said support;
dispersed nanoparticles or a continuous or discontinuous film, of one or more metal(s) or one or more metal alloy(s), on the said uniform, homogeneous, and continuous film;

the said method comprising the following successive steps:

a)—impregnating the heated solid support with a solution of precursor(s) of the metal oxide or metal oxides in a supercritical fluid and depositing the uniform, homogeneous, and continuous film of one or more metal(s) oxide(s) on the said support;

b)—depositing the dispersed nanoparticles or a continuous or a discontinuous film of one or more metal(s) or of one or more metal alloy(s) on said uniform and continuous film, by chemical vapour deposition CVD, from one or more precursors;

the steps a) and b) being carried out in the same chamber, same reactor.

An organic synthesis step may further be carried out between the steps a) and b) and/or after the succession of steps a) and b) of this preferred embodiment.

The inventive method can be defined as a method coupling two technologies, that is on the one hand, impregnation in supercritical medium (SC) and on the other hand, chemical vapour deposition (CVD).

The coupling, combination of the methods of impregnation in supercritical medium and chemical vapour deposition in one and the same reactor, chamber, to prepare a substrate as defined above, has never been described nor suggested in the prior art.

Only methods for impregnating a support by metal salts in supercritical medium alone or methods of chemical vapour deposition CVD alone have been described.

Since the method is carried out in one and the same reactor, the method is considerably simplified and no longer requires any transfer or handling of the support from one apparatus to another apparatus. The duration of the method and the cost thereof are sharply reduced, and so is the size of the installation for its implementation.

It can be stated that the inventive method allows a real improvement from the standpoint of handling catalyst substrates, continuous and discontinuous thin layers deposited on a substrate in particular macroporous, and of their stabilisation for their integration. In fact, the optional heat treatment for stabilising the substrate can also be carried out in situ in the same reactor.

The inventive method has the advantages of the respective methods of impregnation in supercritical medium and chemical vapour deposition, without having any of the drawbacks of said methods, and it has even further advantages resulting from a genuine synergistic effect due to the combination of the two processes.

With regard to the step of impregnation in supercritical medium, it has the advantages already mentioned above in the present description.

Furthermore, during this step, the particular transport properties of the fluids in the supercritical phase allow an effective impregnation of a matrix or solid support, having a simple or complex geometry, whether it is dense or macroporous, such as a filtering support for catalysis.

These properties of the SC fluid give rise to a deposition of a uniform active layer not only from the standpoint of thickness, dispersion of the particles deposited, but also of the structure. The deep impregnation of the filter walls of a catalyst support promotes the exchange in volume and serves to optimise the specific surface area.

With regard to the step of deposition of metal nanoparticles by chemical vapour deposition CVD, it has all the advantages conventionally offered by the CVD process, which is a technology of choice compared with processes such as conventional impregnation by the liquid method or electroplating: in fact, the CVD technology allows the covering of parts having a complex geometry such as catalyst supports (foams, honeycombs, ceramics, zeolites, etc.) with equipment not requiring high vacuum, that is from atmospheric pressure to a hundred Pascals, which makes it a readily industrialisable process. Furthermore, with regard to environmental conservation and particularly air and water, the CVD technology is a “clean” technology, as opposed to polluting synthetic processes such as electroplating.

Furthermore, during the step of nanoparticle deposition by CVD, control of the operating conditions serves to adjust the morphology, size, concentration and dispersion of the nanoparticles, for example of catalysts, and thereby to achieve in particular the synthesis of nanometre sized particles (<20 nm) very finely dispersed (that is of which the inter-particle distance is generally shorter than 50 nm).

Thus, the combination of these two SC and CVD technologies serves to considerably improve the capacity, on the one hand, of locating the catalyst metals in the volume of the parts, and on the other hand, dispersing them at nanometre scale, which permits a significant lowering of the rate of loading with catalyst metals and therefore of the cost of the devices, above all for those using noble metals.

Both the chemical deposition technology for the recovery of pure and dry vapour phase products and the impregnation technology in supercritical medium are clean technologies, because they use very few or no organic solvents which can then, in certain cases, be recycled. In this way, the inventive method, which combines these two clean technologies, is also a clean, non-polluting method.

The two technologies combined in the inventive method are complementary and the inventive method accordingly has a number of surprising advantages deriving from the combination of these technologies, which extend beyond the simple advantages offered independently by each of the said technologies.

In particular, the inventive method serves to highly selectively deposit nanometre sized particles (by CVD), on a uniform continuous film having a large specific surface area (prepared by supercritical fluid or SCF). These technologies are not restrictive in terms of covering complex geometries such as the supports used for the treatment of gaseous effluents, and which are particularly in the form of ceramic foams or honeycombs.

This means that the inventive method can be implemented easily with all sorts of supports, regardless of their geometry, even highly complex, two-dimensional or three-dimensional.

The combination of these two technologies serves in particular to deposit complete catalyst systems within structures which have a complex surface (2D) or volume (3D).

These catalysts are for example in the form of continuous and uniform thin films and/or nanometre sized particles, for example from 1 to 400 nm in diameter and well dispersed on the surface of a dense or porous support.

Finally, one of the essential advantages of the inventive method, apart from its implementation in one and the same reactor, is the use, during each of the steps, of impregnation by a supercritical fluid or deposition of nanoparticles by CVD, of organometallic precursors or metal salts which may advantageously be identical, thereby considerably simplifying the devices to be provided for the storage, transfer and introduction of these precursors in the reactor.

In other words, the difference between the conventional methods, in particular of catalyst deposition and the method of the present invention is in particular the coupling of two processes preferably using the same organometallic precursors or metal salts and suitable for preparing a wash-coat followed by the dispersion of nanoparticles of noble or non-noble metals in one and the same reactor.

The method of the present invention also has the advantage that it allows, in a single chamber, the fabrication of complete catalytic systems which have direct applications in the field of air treatment, for example for the treatment of volatile organic compounds VOC, nitrogen oxides NOx, or for the generation of hydrogen by reforming.

The solid support may be a dense support or a porous, or more precisely macroporous support.

Macroporous support generally means, for example, foams such as ceramic foams having a porosity of a few ppi to several tens of ppi (pores per inch), and/or supports having a honeycomb structure with a few cpsi (channels per square inch) to several hundred cpsi.

The solid support may consist of a material selected from ceramics; metals and metal alloys such as steel; polymers; zeolites; silicon; glass; fabrics; and composites comprising a plurality of the above mentioned materials.

Ceramics are the preferred materials.

This or these ceramics may be selected from ceramic oxides, single or mixed, nitrides and carbides. Advantageously, these ceramics are selected from cordierite (2Al₂O₃.2SiO₂.5MgO), silicon carbide (SiC), alumina/titanium dioxide (Al₂O₃/TiO₂), alumina/zirconia (Al₂O₃/ZrO₂), titanium dioxide (TiO₂), alumina (Al₂O₃), zirconia (ZrO₂), and silica (SiO₂).

As indicated above, the inventive method may be implemented with supports having a complex geometric structure, for example a two-dimensional or three-dimensional macroporous structure. A complex geometric structure generally means supports having varied shapes, with controlled porosity and pressure drops.

For example, these supports may be in the form of foams, honeycombs, porous tubes, granules, vermicelli, beads, or fibres.

The support may, for example, be in the form of a honeycomb or a ceramic foam, for example an Al₂O₃/TiO₂ foam, or even fibres.

The metal oxide or oxides of the uniform and continuous film or of the uniformly dispersed particles may be selected from oxides of aluminium, cerium, barium, zirconium, titanium, vanadium, mixed oxides of these metals, mixtures of these oxides and mixed oxides, and zeolites.

The uniform and continuous film or the uniformly dispersed particles may, for example, be of Al₂O₃, of CeO₂—ZrO₂, of BaO₂, of a zeolite, of TiO₂/V₂O₅, of a mixture of Al₂O₃, CeO₂, BaO, ZrO₂.

During step a), the support or the underlying layer (already deposited) on which the film or dispersed particles are deposited, is generally heated to a temperature of 150 to 400° C. for example.

During step a), the precursors of the metal oxide or oxides are generally selected from organometallic precursors and metal salts of the metals mentioned above, metals whereof the oxides constitute the uniform and continuous film or the uniformly dispersed particles prepared during step a).

The organometallic precursors are generally selected from metal alkoxides, metal β-diketonates and metal carboxylates, these metals being those whereof the oxides constitute the film or the particles prepared in step a).

The film that may be prepared in step a) is a uniform, homogeneous, and continuous film, that is it completely covers the surface of the support, regardless of the geometry thereof, and it leaves no part of the support surface uncovered, even in any possible cavities, voids, reliefs, hollows in the support.

The film, which may be prepared during step a), may in general be qualified as a “thin” film, whereof the thickness is generally from 50 to 800 nm, preferably from 80 to 150 nm.

Supercritical fluid means that the fluid is present at a pressure higher than its critical pressure P_{c} and at a temperature higher than its critical temperature T_{c}.

The temperature and pressure of the fluid are generally respectively between 100 and 600° C. and between 10 and 50 MPa.

The fluid used may be selected, for example, from carbon dioxide, sulphur hexafluoride, nitrous oxide, dinitrogen monoxide, light alkanes having, for example, from 1 to 6 carbon atoms, such as methane, ethane, propane, butane, isobutane, pentane, hexane, alkenes from 1 to 5C, such as ethylene and propylene, and also certain organic liquids, such as methanol, ethanol, isopropanol and butanol.

It is obviously possible to use any compound having a supercritical state, and whose use remains compatible with the material or materials constituting the support and the precursors.

Carbon dioxide is preferred because it has the advantage of relatively easy use: it is inexpensive, non-toxic, non-flammable, and has readily accessible critical conditions (critical pressure: Pc of 7.3 MPa and critical temperature Tc of 31.1° C.)

Furthermore, the supercritical fluid is selected so that it provides excellent solubilisation of the precursors.

During step a), the film is deposited by a sol-gel process and/or a thermal decomposition process.

These processes are processes well known to a person skilled in the art in this technical field.

The sol-gel and/or thermal decomposition processes are processes involving a complex reaction mechanism of hydrolysis, polycondensation and thermal decomposition of the organometallic precursors in supercritical fluid medium.

Moreover, an organic synthesis process may be carried out independently and after step a) and/or step b).

Among the organic synthesis processes, mention may be made for example of processes of interfacial polycondensation, emulsion polymerisation and dispersion polymerisation, which are used for coating metal particles with a polymer.

Advantageously, on completion of step a) and prior to step b), the reactor is purged and cleaned by flushing the support with the supercritical fluid of the support upon which the uniform and continuous film or the dispersed particles of one or more metal oxides are deposited.

The metal or metals deposited during step b) are generally selected from metals called “noble” of columns VIIIB and IB of the Periodic Table of Elements, and non-noble metals having catalytic activity such as Ag and Cu and Ni, and the alloy or alloys deposited during step b) are generally selected from alloys of these metals together and alloys of these metals with other metals.

Advantageously, the metal or metals is(are) selected from silver, rhodium, platinum, palladium, iridium, copper, nickel, and gold.

In the case of nanoparticles or of a continuous alloy film, the latter is preferably selected from alloys of noble and non-noble metals in columns VIIIB and IB of the Periodic Table of Elements such as Ag, Rh, Pt, Pd, Ir, Cu, Ni and Au together.

It is thus possible according to the invention to prepare particles of binary alloys of Ag/Rh, particles or ternary alloys such as Ag/Pt/Rh, or composite particles comprising at least one metal and at least one oxide, such as an oxide of an alkali, alkaline-earth or rare earth metal.

Furthermore, the inventive method may be used to deposit particles or a continuous or discontinuous film made exclusively of a single metal such as Ag, Pt or Au, or an alloy, or several different particles may be deposited simultaneously, each of which consist of a different metal or alloy.

During step b), the deposition may be carried out in the presence of a gas comprising an oxidising reactive gas or a reducing reactive gas.

The gas may comprise more than 50% by volume, preferably more than 70% by volume, preferably even 100% by volume of an oxidising reactive gas.

The deposition then generally occurs in the form of dispersed particles, particularly in the case of silver, or of a discontinuous film.

For other gas compositions, particularly in the case of silver, the deposit is rather generally in the form of a continuous film.

The oxidising reactive gas may be selected from oxygen, carbon dioxide, ozone, dinitrogen monoxide N₂O and mixtures thereof.

The reducing reactive gas may be selected from hydrogen, ammonia, alcohol vapours, hydrocarbons and mixtures thereof.

The gas in the presence of which the deposit is made may be a mixture of the oxidising reactive gas or of the reducing reactive gas and of an inert gas.

The inert gas may be selected from argon, nitrogen, helium and mixtures thereof.

When the gas consists of a mixture of an oxidising gas and an inert gas, and the ratio of the flow rate of the oxidising gas to the flow rate of inert gas is higher than 1, a deposit of particles, in particular of silver, dispersed on the support, or a discontinuous film, is generally obtained.

The same precursors may be used in steps a) and b).

In step b), the precursors are generally selected from organometallic compounds such as metal carboxylates and metal β-diketonates; and metal salts such as metal nitrates.

The precursor or precursors may be used in the form of a solution of these precurors in an organic solvent.

The concentration of the precursor of precursors in the solution may be from 0.01 to 0.6 mol/l.

This solvent generally has an evaporation temperature lower than the decomposition temperature of the precursor or precursors.

The solvent is generally selected from organic compounds which are liquid at ambient temperature and up to 200° C. under standard pressure conditions.

Thus, the solvent may be selected from mesitylene, cyclohexane, xylene, toluene, n-octane, isopropanol, tetrahydrofuran, acetylacetone, ethanol, water and mixtures thereof.

The solution, particularly in the case in which the precursors is (are) a precursor of silver or a silver alloy, may further comprise an amine and/or a nitrile.

In step b), the deposit is generally obtained at a support temperature lower than or equal to 500° C., preferably lower than or equal to 300° C., even more preferably from 250 to 290° C.

In step b), the deposit may be carried out atmospheric pressure or under vacuum, preferably at a pressure of 300 Pa to 1000 Pa.

The duration of the deposition in step b) is generally 2 to 90 minutes, preferably 5 to 30 minutes.

The deposition in step b) may be carried out with plasma enhancement.

Depending on the conditions under which the deposition in step b) is carried out, a continuous film of metal or metal alloy may be obtained, or the deposit consists of dispersed, discrete particles, the said particles may have a size of 1 to 400 nm, preferably 1 to 100 nm, even more preferably from 5 to 50 nm, and a density of 10 to 500 μm⁻², preferably of 50 to 200 μm⁻².

Some of the particles may join to form a discontinuous, porous film on the surface of the support, that is, of the oxides layer.

Advantageously, on completion of step a), a heat treatment is carried out for example at 400 to 800° C. for 3 hours to stabilise the oxides layer, or the continuous or discontinuous film or the dispersed particles of metal or metals alloy.

The invention further relates to a device for implementing the method according to claim 1, comprising:
a chamber or reactor in which a solid support is placed;
means for bringing a fluid to the supercritical state;
means for dissolving one or more metal oxide(s) precursor(s) in the supercritical fluid;
means for conveying the solution of precursors of the metal oxide or oxides in the supercritical fluid to the reactor, in contact with the support or with an already deposited layer; whereby a uniform, homogeneous, and continuous film or uniformly dispersed particles of one or more metal oxide(s) are deposited on the said support or on the said layer;
means for withdrawing the supercritical fluid on completion of the deposition, from the reactor, expanding it, separating the unreacted precursors from the fluid and recycling the said fluid to the reactor;
means for conveying to said reactor a gas containing one or more precursor(s) of one or more metal(s) or metals alloy(s);
means for heating the support or an already deposited layer;
means for placing the reactor under vacuum or under pressure.

This device has in particular all the advantages inherent in the method that is carried out by said device and which have already been described above. In particular, it serves to carry out in one and the same reactor the deposition of several layers by CVD and FSC impregnation, as well as any optional heat treatments.

The invention will now be described in greater detail in the following description, provided for illustration and non-limiting, in conjunction with the appended drawings, in which:

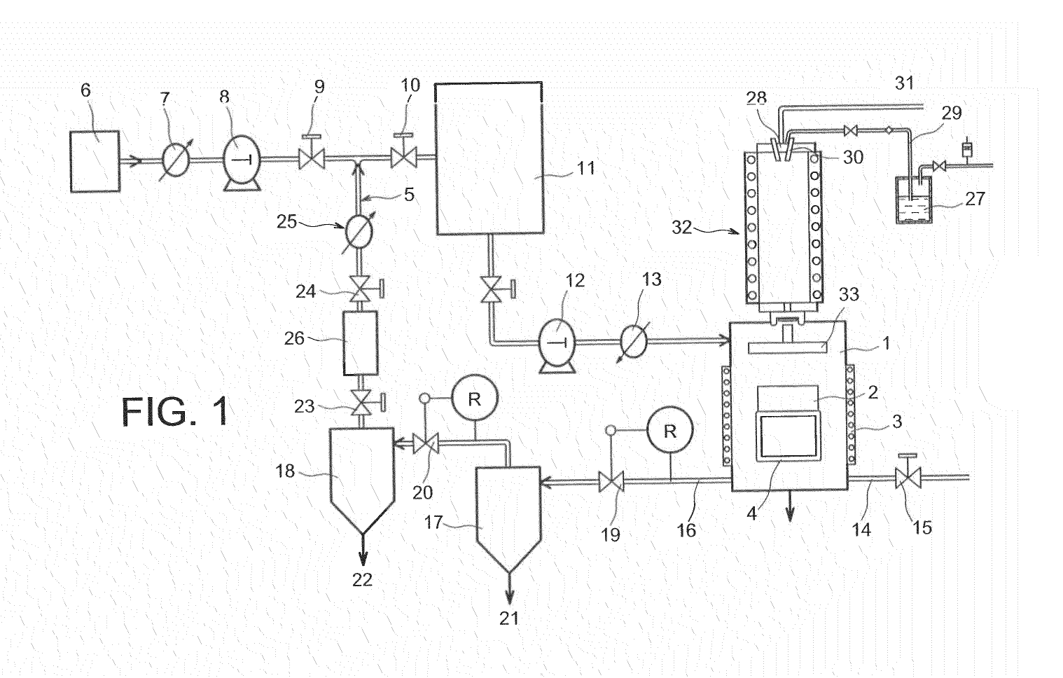

FIG. 1 is a flow chart vertical cross section of an installation for implementing the inventive method;

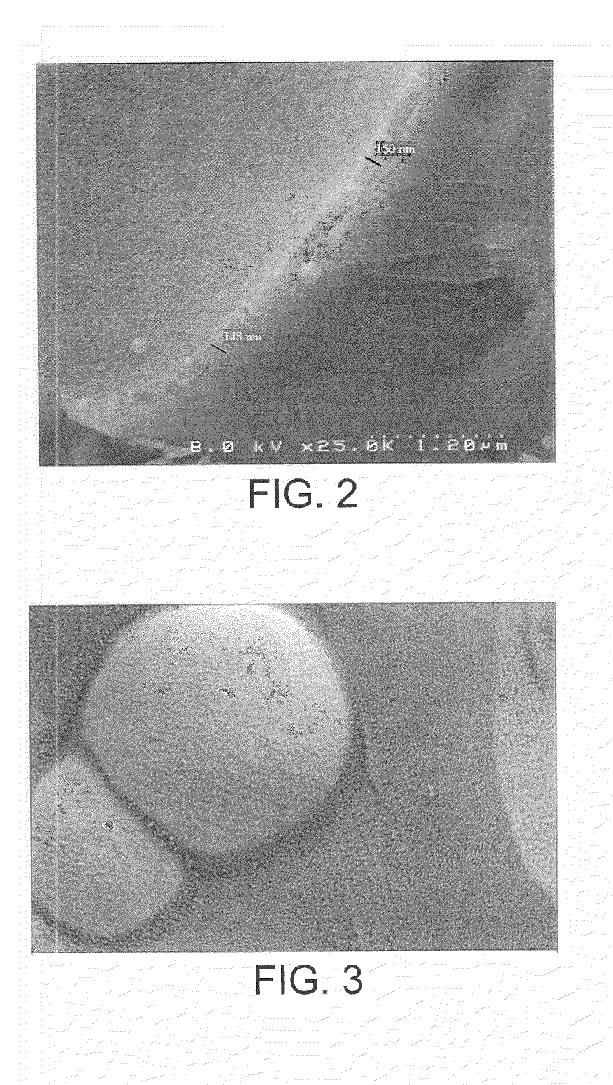

FIG. 2 is a microphotograph taken by scanning electron microscope (SEM-FEG) showing a layer of oxides Al₂O₃, CeO₂, BaO, ZrO₂ prepared on a porous ceramic support consisting of an alumina-zirconia foam with 20 ppi (pores per inch) in the conditions of example 1 (Step 1 of the inventive method). The magnification used is 25 000. The scale shown in FIG. 2 is 1.20 μm.

The dark marks in the figure indicate the layer thicknesses of 148 nm and 150 nm.

FIG. 3 is a microphotograph taken by a scanning electron microscope (SEM-FEG) showing platinum nanoparticles, prepared according to the second step of the inventive method, on the oxide layer prepared in example 1, and in the conditions of example 2. The magnification used is 50 000.

The scale shown in FIG. 3 is 1 μm.

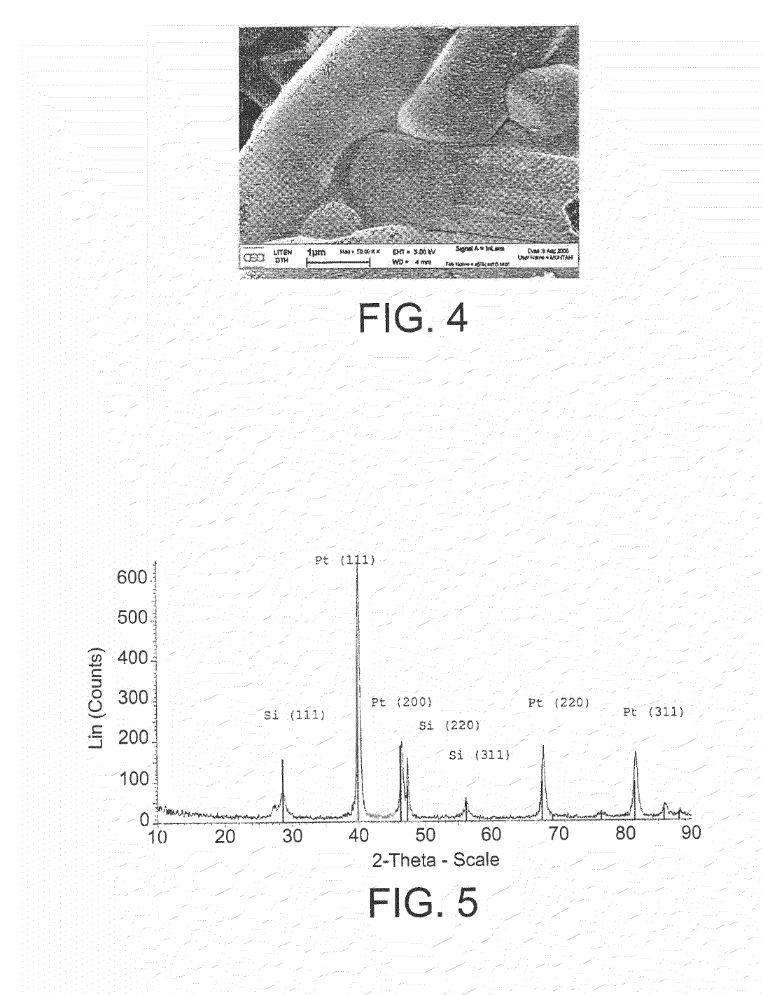

FIG. 4 is a microphotograph taken by scanning electron microscope (SEM-FEG) showing platinum nanoparticles, prepared according to the second step of the inventive method, on the oxide layer prepared in example 1, and in the conditions of example 2. The magnification used is 50 000.

The scale shown in FIG. 4 is 1 μm.

FIG. 5 is an X-ray diffraction spectrum of the deposit of Pt nanoparticles deposited by MOCVD in example 2 (FIGS. 2, 3 and 4).

In the spectrum, 20 is plotted on the x-axis and the arbitrary intensity of the x-rays is plotted on the y-axis.

It should be noted that in the detailed description that follows, the preferred embodiment of the inventive method is described in particular, in which steps a) then b) are carried out in succession on a solid support, and the installation used for the implementation of this preferred embodiment. A person skilled in the art can easily make the necessary adjustments to reverse, alternate and/or repeat the said steps a) and b).

FIG. 1 shows the flow chart vertical section of an installation for implementing the inventive method, coupling the processes of chemical vapour deposition and deposition in supercritical medium.

It is obvious that such a figure only shows one exemplary embodiment of an installation and that it is only provided for illustration and is non-limiting.

The installation comprises an autoclave, or reactor (1) in which the support (2) is placed, this autoclave, reactor, according to the invention, performing the role of a chamber for impregnation, deposition in supercritical medium, and then the role of a CVD deposition chamber.

Such an autoclave, reactor, or deposition chamber (1) is capable of withstanding the pressure applied in the inventive method in the supercritical step and it is also provided with heating and temperature control means in the form of a thermostatically controlled double jacket (3), in which an appropriate coolant, heat conductor, circulates, or of electric heating resistors.

The volume of the autoclave, or reactor (1) is variable, and depends in particular on the volume of the support on which the depositions are carried out, and can be easily determined by a person skilled in the art.

The chamber, reactor, accommodates the support (2) or the supports on which the depositions must be made, these supports are preferably placed on one or more support element(s) or grid(s) (4).

The support may have any shape because the inventive method allows the deposition of oxides followed by metal particles, for example silver particles, even on substrates which have a very complex geometry. The support may be selected from porous supports or from dense, non-porous supports.

The support may have any surface texture, and may be rough or smooth.

The size of the substrate is not limited, so that small and large substrates can receive a deposit by the inventive method.

The support may be made of a variety of materials (inorganic, organic or composite), and even of a material that is relatively sensitive to heat, thanks to the relatively low deposition temperatures employed.

The support may for example be made of a material as defined above.

In FIG. 1, the installation shown only comprises a single chamber, reactor, autoclave (1), but it is obvious that the installation may comprise a plurality of chambers, for example 2 to 10, placed in series for example.

The installation comprises a first portion connected to the deposition chamber more particularly intended to implement the first step of the inventive method, which is carried out in supercritical medium.

Thus, the installation according to the invention comprises means for bringing a fluid, such as CO₂ to the supercritical state, and to transfer this fluid to the chamber.

In FIG. 1, the fluid, CO₂ for example, issuing from a recycling line (5), and/or optionally from a make-up and storage tank, for example of CO₂ (6) (via a condenser (7), a pump (8) and a valve (9)), enters, via a valve (10), a liquefaction tank (11) provided with temperature control means (not shown) for example in the form of a thermostatically controlled double jacket, in which an appropriate coolant, heat conductor, fluid circulates.

The said fluid, such as CO₂, is thus liquefied and then pumped and compressed by means of a pump (12), for example, a diaphragm or piston type compression pump or, for example, a compressor, towards the chamber, reactor (1).

Before being introduced into the extractor (1), the fluid, for example, pumped CO₂, is heated in a heat exchanger (13), called a “supercritical” exchanger, in which it is heated to conditions in which it is in the form of a dense pressurised fluid, in particular a dense supercritical fluid. This means that the fluid, in this heat exchanger (13) is heated above its critical temperature which is, for example, 31.1° C., in the case of CO₂.

The precursors are introduced directly into the reactor after the introduction of the support. A line (14) provided with a valve (15) is also provided to introduce the supercritical fluid and the precursors into the chamber (1) if they are mixed in an independent reactor (not shown).

Upon completion of the impregnation operation in supercritical medium, which is step a) of the inventive method, a stream of fluid such as CO₂, in which the unreacted precursors are solubilised, is removed from the chamber (1) via the line (16) and is then sent to separating means connected to the autoclave, reactor (1) and comprising, for example, two cyclone type separators (17, 18) connected in series, each of them preceded by an automatic relief valve (19, 20).

Two cyclone type separators (17, 18) are shown in FIG. 1, but it is obvious that the number, type and succession of separators may vary.

The expansion to which the fluid is subjected takes place at constant temperature.

In each of the separators (17, 18), a separation or demixing occurs, on the one hand, of the unreacted precursor compounds which are in the form of a liquid and, on the other hand, of a gas, for example CO₂.

The precursor compounds are withdrawn (21, 22), for example, at the base of the separators, and recovered, and then optionally subjected to new separation, extraction or purification operations, for example centrifugation, settling or liquid/liquid extraction, or destroyed.

The gas issuing from the separation, such as CO₂, is stripped, and then sent to the fluid recycle means, which essentially comprise, in addition to the valves (23, 24), a line (5) and a “cold” heat exchanger (25) (condenser, liquefier) for example, in the form of a thermostatically controlled chamber. The gas is then sent to the liquid reserve (11) at low temperature, maintained by means of a refrigerant bath which cools and liquefies the fluid, such as CO₂.

The stripping means (26) are shown in FIG. 1 by a reflux column or an active charcoal column (26) placed on the fluid recycle means.

Finally, the installation comprises control means (not shown except for the control of the valves 19, 20), in particular for controlling the pressure, in the various parts of the process, which comprise a control circuit composed of pressure sensors, controllers and pneumatically controlled needle valves.

The installation further comprises a second part connected to the deposition chamber (1) and more particularly intended to implement the second step of the inventive method, that is the step of deposition of a continuous or discontinuous layer of a metal or alloy or of dispersed nanoparticles of metals or metal alloys, by chemical vapour deposition CVD.

More precisely, for the implementation of the second step of the inventive method, the composition, generally in liquid form, containing the precursor or precursors, is generally first sent to a vaporisation device or vaporiser.

The composition containing the precursor or precursors is preferably in the form of a solution of the precursor or precursors in a solvent, the said solution preferably comprises a nitrile and/or an amine to promote the dissolution of the precursor in the solution, in particular if the precursor in question is a silver precursor.

The concentration by volume of the amine and/or nitrile in the solution is generally higher than 0.1%, preferably from 0.5 to 10%.

The amine is generally selected from monoamines such as n-hexylamine, isobutylamine, disecbutylamine, triethylamine, benzylamine, ethanolamine and diisopropylamine; polyamines; and mixtures thereof.

The nitrile is generally selected from acetonitrile, valeronitrile, benzonitrile and propionitrile and mixtures thereof.

The precursor or precursors are generally organometallic compounds or metal salts such as metal nitrates. The solution may contain only one precursor, which is then, for example, an organometallic compound of silver. If the solution contains a plurality of precursors, one of these precursors may then be a precursor of a first metal, for example an organometallic compound of silver, and the other precursor or precursors are organometallic compounds of other metals different from the first metal, for example different from silver, in order to form, on the substrate, an alloy of this first metal, such as silver, and of this other metal or these other metals.

We have shown above that the preferred organometallic precursors, both of silver and of the other metals, are selected from metal alkoxides, β-diketonates and carboxylates having the formula M(C₂CR) where M is a metal and R is defined below.

Thus, the preferred silver precursors are selected from β-diketonates such as silver tetramethylheptanedioate and silver carboxylates. A particularly preferred silver precursor is silver pivalate, which serves to overcome the problems of low volatility encountered with precursors such as silver carboxylates Ag(O₂CR) where R is an alkyl group preferably with 3 to 7C, and also problems of contamination generally encountered with fluorinated organometallic precursors.

Advantageously, according to the invention, the same precursors are used in step a) (FSC) and in step b) (CVD) whereby the reactants storage and feed means are simplified.

At the outlet of the vaporisation device, the composition, for example the vaporised solution, containing the precursors is introduced into the chamber (1) already described, which contains the support upon which a continuous layer or dispersed nanoparticles are to be deposited.

Before its arrival in the vaporisation device, the composition such as a solution is generally maintained in a tank (27) at ambient temperature.

The precursor composition can be vaporised by means of various devices known to a person skilled in the art.

By way of a preferred example, mention may be made of the device described in Chem. Mat. 13, 3993 (2001), sold by Jipelec under the name “Infect, System for injection and evaporation of liquid precursors, pure or in solution form”. The temperature of the support to be coated, which is generally confused with the temperature in the deposition chamber and which can be defined as being the deposition temperature, is 100 to 800° C. according to the invention.

Preferably, a relatively low temperature is used, that is lower than or equal to 500° C., preferably lower than or equal to 300° C., even more preferably from 250 to 290° C., for example 280° C.

Such a low temperature has the advantage of allowing the deposition of metal or alloy particles, for example of silver, on thermally fragile substrates, which would not have been feasible by other methods, taking place at much higher temperatures.

The deposition chamber for this step b) of the method consists of the closed reactor, tank already described above and used in the first step, but in which the prevailing atmosphere consists of a gas called reaction gas.

This gas may comprise for example in the majority (by volume), an oxidising reactive gas when it is desired in particular to deposit dispersed particles particularly of silver. However, the reaction gas may also be a reducing gas such as H₂.

The pressure in the deposition chamber (1) may in this CVD step be the atmospheric pressure or a lower pressure (chamber under vacuum) for example a pressure lower than or equal to 15 Torr.

The inventive method may advantageously be carried out with plasma enhancement assistance.

Plasma enhancement techniques are complementary to chemical vapour deposition processes using organometallic precursors in the sense in which they also allow for low reaction temperatures (techniques called PA or PE-CVD, that is “Plasma Assisted” or “Plasma Enhanced Chemical Vapour Deposition”).

The type of plasma excitation may be selected for example from low frequency (LF), radiofrequency (RF) or pulsed direct current (pulsed DC) plasma excitations.

Plasma enhancement serves to provide additional surface structuring possibilities.

A cold plasma can therefore optionally be added around the support. When the deposition is carried out in the presence of plasma, it is sufficient for the support, substrate, intended to receive the nanoparticles of metal or metals alloy, for example of silver or a silver alloy, to be maintained at the same temperature prevailing in the evaporator. In the absence of plasma, it is necessary for the said support to be at a temperature higher than that of the evaporator, the temperature difference being at least 20° C., preferably at least 50° C., in order to prevent the deposition of metal, for example silver, on the reactor walls.

When the gas employed consists of a majority of an oxidising gas, then the change in the surface and grain boundaries energies caused by the use of this oxidising gas serves to prepare deposits of dispersed nanoparticles of metal or metals alloy, for example of silver or silver alloy, for example discontinuous films, at relatively low deposition temperatures defined above.

As already stated above, the deposit obtained by the inventive method may in this case, in particular be defined as a porous film in the form of nanometer sized metal islands, that is generally having a size, diameter for example of 1 to 400 nm, well dispersed on the surface of the substrate, support whether the latter is dense or porous, giving them a large active surface, which is a crucial factor for catalyst applications for example.

The composition, morphology and in particular, the porosity of the deposits of nanoparticles of metal or metals alloy, for example of nanoparticles of silver or nanoparticles of silver alloy, obtained by the inventive method, can be controlled, adjusted, by adjusting a number of parameters such as the type and flow rate of reactive gas, the quantity of precursor, the temperature and pressure, provided however that in this case, the gas in the presence of which the deposition is carried out always contains a majority proportion by volume of oxidising gas, in particular with a ratio of oxidising gas/inert gas flow rates greater than >1.

The implementation of the inventive method serves to obtain nanoparticles based on metal, for example based on silver, having good adhesion to the supports on which they have been deposited. The size of the nanoparticles varies according to the processed parameters and in particular according to the ratio of the oxidising gas/inert gas flow rates (always remaining with the ratio >1), the flow rate of the metal precursors and, finally, the time of the experiment. In general, the films are non-conductive and have a matte appearance.

When the quantity of oxidising gas used in the gas is lower than or equal to 50% by volume, it is possible to obtain continuous films. Similarly, when a gas comprising a reducing gas is used, it is possible to obtain continuous or discontinuous deposits.

An installation that is particularly suitable for the implementation of the inventive method and which is the one used in the examples below comprises a vaporisation device of the “InJect” type mentioned above sold by JIPELEC, coupled with a chemical vapour deposition chamber.

The “InJect” device comprises four main parts:
the tank or tanks (27) for storing the chemical solution or solutions of precursors; in the case in which the continuous or discontinuous film or the nanoparticles consist of a single metal, a single storage tank (27) is provided; in the case of alloys whereof the dissolution of the organometallic precursors cannot be carried out in a common solvent, a plurality of storage tanks are used;
one or more injectors (28), for example of the gasoline or diesel engine injector type connected by one or more feed line(s) (29) equipped with filter(s) (30) to the liquid storage tank(s) (27) and which is controlled by an electronic control device;
a line for the supply of vector gas (31) or inert carrier gas (for example nitrogen) culminating in the injector (28);
and a vaporisation device (32) (evaporator).

The chemical vapour deposition chamber, which contains the substrate to be coated, comprises heating means, an oxidising reactive gas feed such as oxygen introduced between the vaporisation system and the inlet of the deposition chamber, and pumping and pressure control means, said pressure being reduced if operating under vacuum. The evaporator is connected to the chemical vapour deposition chamber by a line equipped with heating means, which is kept at the same temperatures as the evaporator, and which is connected in the chamber to a gas distributor (33).

The chemical vapour deposition chamber and the substrate to be coated placed therein are generally maintained in this step b) at a temperature above that of the evaporator in order to create a positive thermal gradient. The chemical solution containing the precursor or precursors is introduced into the tank maintained under pressure at a pressure of 1 or 2 bar, for example, and then sent from the said reservoir, via the injector(s) (by pressure differential) into the evaporator, which is maintained under vacuum. The injection flow rate is controlled by adjusting the frequency and time of opening of the injector(s) which may be considered as a micro-solenoid valve and which is controlled by a computer.

The chemical reaction occurs in the presence of a reaction gas comprising a reactant gas, such as O₂, H₂ or CO₂, and under a pressure generally lower than or equal to 2000 Pa.

In particular, due to the chemical composition (at least one noble metal which may be platinum or a non-noble metal such as silver and optionally a plurality thereof) and the morphology (large number of very well dispersed nanometer sized active sites) of the namomatierals of the invention (that is the substrates on which the nanometer sized particles for example of silver or silver alloy are dispersed), they appear to be candidates of choice in the fields of electronics, optics and above all, catalysis, for example for environmental conservation.

For example, they accordingly have direct applications for gas phase oxidation (air pollution control) and aqueous phase oxidation (water pollution control), but they can also serve as membranes for hydrogen permeation (gas reforming for fuel cells, hydrogenation/dehydrogenation) or even for catalysing other reactions in the field of fuel cells.

The invention will now be described with reference to the following examples provided for illustration and non-limiting.

### EXAMPLES

### Example 1

In this example, the deposition of a layer of oxides consisting of Al₂O₃, CeO₂, BaO, ZrO₂ on a porous ceramic support consisting of an alumina-zirconia foam (Al₂O₃/TiO₂) having 20 ppi (pores per inch) is carried out by impregnation in supercritical CO₂ medium.

The deposition is carried out from a chemical solution comprising the organometallic precursors dissolved in an alcohol solvent (hexylene glycol or isopropanol). The final composition of the solution is given in Table 1:

TABLE 1

| | % by | |
|---|---|---|
| | weight | Precursors |
| Alumina Al₂O₃ | 12.9 | Aluminium tri-sec-butoxide |
| Zirconia ZrO₂ | 2.2 | Zirconium propoxide |
| Cerine CeO₂ | 2.4 | Cerium acetylacetonate hydrate |
| Barium oxide BaO | 1.4 | Barium acetylacetonate hydrate |
| Solvent | 81.1 | Hexylene glycol |
| | | (2-methyl pentane-2,4-diol)Isopropanol |
| | | (2-propanol) |

The temperature and pressure conditions are set respectively at 300° C. and 30 MPa. The contact time in the reactor between the reactants and the support is 1 hour.

In the case of this test, a perfect impregnation of the macroporous matrix is obtained, with the deposition of a uniform active layer that is stable at high temperature (FIG. 2).

### Example 2

On the wash coat prepared in Example 1, platinum nanoparticles can be deposited by chemical vapour deposition CVD.

For the deposition conditions below, the platinum nanoparticles are prepared on a porous ceramic substrate (alumina-zirconia foam 20 ppi).

The chemical deposition solution comprises the organometallic precursor of platinum (acetylacetonate), dissolved in a solvent (acetylacetone).

The temperatures of the evaporator and the substrate are set respectively at 220 and 340° C. The other operating conditions are given in Table 2 below:

TABLE 2

| | | Injector | Injector | Flow rates | | |
|---|---|---|---|---|---|---|
| | Concentration | frequency | opening time | N₂/O₂ | Pressure | Deposition |
| | (Mol/l) | (Hz) | (ms) | (cc) | (Pascal) | time (min) |
| Test A | 0.03 | 2 | 2 | 40/160 | 800 | 30 |
| Test B | 0.03 | 2 | 2 | 40/160 | 800 | 20 |

In the case of these two tests A and B, a crystallised deposit is obtained (see FIGS. 3 and 4: FIG. 3 corresponding to test A and FIG. 4 to test B) having a cubic structure, comprising uncoalesced platinum nanoparticles 5 to 20 nm in diameter; the density of the nanoparticles is close to 10¹² cm⁻² in this case.

### Characterisation of Deposits Obtained in Examples 1 and 2

Characterisation by Scanning Electron Microscopy

The characterisation by scanning electron microscopy of the oxides layer prepared in Example 1 (FIG. 2) is first carried out.

The characterisation by scanning electron microscopy of the deposit comprising platinum nanoparticles of Example 2 (FIGS. 3 and 4) is then carried out.

Characterisation by X-Ray Diffraction Spectroscopy

The characterisation is carried out by X-ray diffraction spectroscopy of the deposit of platinum nanoparticles of Example 2 (the deposit obtained in Example 2 and in FIGS. 3 and 4): FIG. 5.

### REFERENCES

[1] J. Jung, M. Perrut, Journal of Supercritical Fluids, 20 (2001), 179-219.
[2] F. Cansell, B. Chevalier, A. Demourgues, J. Etourneau, C. Even, V. Pessey, Journal of Materials Chemistry, 9 (1999), 67-75.
[3] McLaughlin, F. David, Skriba and C. Michael, U.S. Pat. No. 4,916,108, 1990.
[4] P. Serp, R. Feurer, R. Morancho, P. Kalck, Journal of Catalysis, 157 (1995), 294-300.

1. A method for preparing a substrate comprising a solid support and a plurality of layers on the support;
at least one layer consisting of a uniform, homogeneous, and continuous film of particles of one or more metal oxide(s), or of uniformly, homogeneously, dispersed particles of one or more metal oxide(s), on the support or on an underlying layer;
at least one layer consisting of a continuous or discontinuous film of one or more metal(s) or of one or more metal alloy(s), or of dispersed nanoparticles of one or more metal(s) or of one or more metal alloy(s), on the support or on an underlying layer;
the method comprising the following steps:
a)—impregnating the heated solid support or an already deposited underlying layer with a solution of precursors of the metal oxide or oxides in a supercritical fluid, and depositing a uniform, homogeneous, and continuous film of particles of one or more metal oxide(s), or uniformly, homogeneously, dispersed particles of one or more metal oxide(s), on the support or on the underlying layer
b)—depositing a continuous or discontinuous film of one or more metal(s) or of one or more metal alloy(s), or dispersed nanoparticles of one or more metal(s) or of one or more metal alloy(s), on the support or on an underlying layer, by chemical vapour deposition CVD, from one or more precursors;
the steps a) and b) being carried out in the same chamber, same reactor.

2. The method according to claim 1, in which a step a) followed by a step b) are carried out in succession.

3. The method according to claim 1, in which step b) followed by step a) are carried out in succession

4. The method according to claim 1, wherein each of the steps a) or b) or the succession of steps a) and b) or b) and a) is repeated from 1 to 10 times.

5. The method according to claim 1, wherein an organic synthesis step is carried out after a step a) and/or a step b).

6. The method according to claim 1, in which the following Successive steps are carried out:
a)—impregnating the heated solid support with a solution of precursor(s) of the metal(s) oxide(s) in a supercritical fluid and depositing the uniform, homogeneous, and continuous film of one or more metal(s) oxides(s) on the support;
b)—depositing dispersed nanoparticles or a continuous or discontinuous film of one or more metal(s) or of one or more metal alloy(s) dispersed in the uniform, homogeneous, and continuous film, by chemical vapour deposition CVD, from one or more precursors.

7. The method according to claim 6, in which an organic synthesis step is carried out between the steps a) and b) and/or after the succession of steps a) and b).

8. The method according to claim 5, in which the organic synthesis is carried out by a method selected from the process of interfacial polycondensation, emulsion polymerisation and dispersion polymerisation.

9. The method according to claim 1, in which the solid support is dense or macroporous.

10. The method according to claim 1, wherein the support is in the form of a foam, in particular ceramic, a honeycomb, a porous tube, or granules, vermicelli, beads or fibres.

11. The method according to claim 1, in which the solid support consists of one or more material(s) selected from ceramics; metals and metal alloys such as steel; polymers; zeolites; silicon; glass; fabrics; and composite materials thereof.

12. The method according to claim 11, in which the ceramics are selected from single or mixed oxide ceramics, nitrides and carbides.

13. The method according to claim 12, in which the ceramics are selected from cordierite (2Al₂O₃.2SiO₂.5MgO), silicon carbide (SiC), alumina/titanium dioxide (Al₂O₃/TiO₂), alumina/zirconia (Al₂O₃/ZrO₂), titanium dioxide (TiO₂), alumina (Al₂O₃), zirconia (ZrO₂), and silica (SiO₂).

14. The method according to claim 13, in which the solid support is a foam of Al₂O₃/TiO₂.

15. The method according to claim 1, wherein the metal oxide or oxides of the uniform and continuous film or of the uniformly dispersed particles are selected from oxides of aluminium, cerium, barium, zirconium, titanium, vanadium, mixed oxides of these metals, mixtures of these oxides and mixed oxides, and zeolites.

16. The method according to claim 1, wherein the precursor or precursors of the metal oxide or oxides are selected from organometallic compounds and metal salts.

17. The method according to claim 16, in which the organometallic precursors are selected from metal alkoxides, metal β-diketonates, metal carboxylates.

18. The method according to claim 1, wherein the uniform and continuous film has a thickness of 50 to 800 nm, preferably of 80 to 150 nm.

19. The method according to claim 1, wherein the supercritical fluid is selected from carbon dioxide, sulphur hexafluoride, nitrous oxide, dinitrogen monoxide, light alkanes having, for example, from 1 to 6 carbon atoms, such as methane, ethane, propane, butane, isobutane, pentane, hexane, alkenes from 1 to 5C, such as ethylene and propylene, and also certain organic liquids, such as methanol, ethanol, isopropanol and butanol.

20. The method according to claim 1, wherein in step a), the temperature and pressure of the fluid are respectively between 100 and 600° C. and between 10 and 50 MPa.

21. The method according to claim 1, wherein during step a), the film is deposited by a sol-gel process and/or a thermal decomposition process.

22. The method according to claim 1, wherein on completion of step a) and prior to step b), the reactor is purged and cleaned by flushing the support with the supercritical fluid.

23. The method according to claim 1, wherein the metal or metals deposited during step b) are selected from metals called “noble” of columns VIIIB and IB of the Periodic Table of Elements, and non-noble metals having catalytic activity such as Ag and Cu and Ni, and the alloy or alloys deposited during step b) are selected from alloys of these metals together and alloys of these metals with other metals.

24. The method according to claim 23, in which the metal or metals is(are) selected from silver, rhodium, platinum, palladium, iridium, copper, nickel, and gold.

25. The method according to claim 23, in which the alloy is selected from alloys of metals in columns VIIIB and IB of the Periodic Table of Elements such as Ag, Rh, Pt, Pd, Ir, Cu, Ni and Au together.

26. The method according to claim 1, wherein the deposition in step b) is carried out in the presence of a gas comprising an oxidising reactive gas or a reducing reactive gas.

27. The method according to claim 26, in which the deposition in step b) is carried out in the presence of a gas comprising more than 50% by volume, preferably more than 70% of the oxidising reactive gas by volume, even more preferably 100% by volume of the oxidising reactive gas.

28. The method according to claim 26, in which the oxidising reactive gas is selected from oxygen, carbon dioxide, ozone, nitrous oxide N₂O and mixtures thereof.

29. The method according to claim 26, in which the reducing reactive gas is selected from hydrogen, ammonia, alcohol vapours, hydrocarbons and mixtures thereof.

30. The method according to claim 26, in which the gas consists of a mixture of oxidising reactive gas and reducing reactive gas and an inert gas.

31. The method according to claim 30, in which the inert gas is selected from argon, nitrogen, helium and mixtures thereof.

32. The method according to claim 30, wherein the gas consists of a mixture of an oxidising gas and an inert gas and the ratio of the flow rate of oxidising gas to the flow rate of inert gas is higher than 1.

33. The method according to claim 1, wherein in step b), the precursors are selected from organometallic compounds and metal salts.

34. The method according to claim 33, in which in step b), the precursors are organometallic precursors selected from metal carboxylates, and metal β-diketonates.

35. The method according to claim 33, in which the metal salts are selected from metal nitrates.

36. The method according to claim 1, wherein during step b) the precursor or precursors in particular organometallic are used in the form of a solution of these precursors in an organic solvent.

37. The method according to claim 36, in which the concentration of the precursor or precursors in the solution is 0.01 to 0.6 mol/l.

38. The method according to claim 36, wherein in which the solvent has an evaporation temperature lower than the decomposition temperature of the precursor or precursors.

39. The method according to claim 38, in which the solvent is selected from organic compounds that are liquid at ambient temperature and up to 200° C. in standard pressure conditions.

40. The method according to claim 39, in which the solvent is selected from mesitylene, cyclohexane, xylene, toluene, n-octane, isopropanol, tetrahydrofuran, acetylacetone, ethanol, water and mixtures thereof.

41. The method according to claim 36, wherein the solution further comprises an amine and/or a nitrile.

42. The method according to claim 1, wherein during step b), the deposition is carried out at a support temperature lower than or equal to 500° C., preferably lower than or equal to 300° C., even more preferably from 250 to 290° C.

43. The method according to claim 1, wherein during step b), the deposition is carried out at atmospheric pressure.

44. The method according to claim 1, wherein during step b) the deposition is carried out under vacuum, preferably at a pressure of 300 Pa to 1000 Pa.

45. The method according to claim 1, wherein the duration of the deposition in step b) is between 2 and 90 minutes, preferably between 5 and 30 minutes.

46. The method according to claim 1, wherein the deposition is carried out with plasma enhancement.

47. The method according to claim 1, wherein the same precursors are used in steps a) and b).

48. The method according to claim 1, wherein during step b), dispersed nanoparticles are deposited.

49. The method according to claim 48, in which the nanoparticles have a size of 1 to 400 nm, preferably 1 to 100 nm, even more preferably from 5 to 50 nm.

50. The method according to claim 48, in which the nanoparticles have a density of 10 to 500 μm⁻², preferably 50 to 200 μm⁻².

51. The method according to claim 1, wherein on completion of step a), a heat treatment is carried out, for example at 400 to 800° C.

52. A device for implementing the method according to claim 1, comprising:
a chamber or reactor in which a solid support is placed;
means for bringing the fluid to the supercritical state;
means for dissolving one or more metal oxide precursors in the supercritical fluid;
means for conveying the solution of precursors of the metal oxide or oxides in the supercritical fluid to the reactor, in contact with the support or with an already deposited layer; whereby a uniform, homogeneous, and continuous film or uniformly, homogeneously, dispersed particles of one or more metal oxide(s) are deposited on the support or the layer;
means for withdrawing the supercritical fluid on completion of the deposition, from the reactor, expanding it, separating the unreacted precursors from the fluid and recycling the fluid to the reactor;
means for conveying to said reactor a gas containing one or more precursors of one or more metals or metal alloys;
means for heating the support or an already deposited layer;
means for placing the reactor under vacuum or under pressure.

53. The method according to claim 2, in which each of the steps a) or b) or the succession of steps a) and b) or b) and a) is repeated from 1 to 10 times.

54. The method according to claim 3, in which each of the steps a) or b) or the succession of steps a) and b) or b) and a) is repeated from 1 to 10 times.

55. The method according to claim 7, in which the organic synthesis is carried out by a method selected from the process of interfacial polycondensation, emulsion polymerisation and dispersion polymerisation.

56. The method according to claim 27, in which the oxidising reactive gas is selected from oxygen, carbon dioxide, ozone, nitrous oxide N₂O and mixtures thereof.

57. The method according to claim 27, in which the gas consists of a mixture of oxidising reactive gas and reducing reactive gas and an inert gas.

58. The method according to claim 28, in which the gas consists of a mixture of oxidising reactive gas and reducing reactive gas and an inert gas.

59. The method according to claim 29, in which the gas consists of a mixture of oxidising reactive gas and reducing reactive gas and an inert gas.

60. The method according to claim 31, wherein the gas consists of a mixture of an oxidising gas and an inert gas and the ratio of the flow rate of oxidising gas to the flow rate of inert gas is higher than 1.

61. The method according to claim 37, wherein in which the solvent has an evaporation temperature lower than the decomposition temperature of the precursor or precursors.

62. The method according to claim 37, wherein the solution further comprises an amine and/or a nitrile.

63. The method according to claim 38, wherein the solution further comprises an amine and/or a nitrile.

64. The method according to claim 39, wherein the solution further comprises an amine and/or a nitrile.

65. The method according to claim 40, wherein the solution further comprises an amine and/or a nitrile.

66. The method according to claim 49, in which the nanoparticles have a density of 10 to 500 μm⁻², preferably 50 to 200 μm⁻².
